(19) United States
(12) Patent Application Publication
(10) Pub. No.: US 2024/0224560 A1
(43) Pub. Date: Jul. 4, 2024

(54) LIGHT-EMITTING DEVICE AND PREPARATION METHOD THEREOF, DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Haowei WANG, Beijing (CN); Xiaoyuan ZHANG, Beijing (CN); Yuanming ZHANG, Beijing (CN)

(21) Appl. No.: 17/921,091

(22) PCT Filed: Dec. 28, 2021
(86) PCT No.: PCT/CN2021/142221

§ 371 Date: Oct. 24, 2022

(51) Int. Cl. H10K 50/115; C09K 11/06; H10K 59/35; H10K 59/38; H10K 85/40; H10K 85/60

(52) U.S. Cl. CPC H10K 50/115; C09K 11/06; H10K 59/35; H10K 59/38; H10K 85/40; H10K 85/60

(57) ABSTRACT

Disclosed are a light-emitting device and a preparation method thereof, a display panel and a display device. The light-emitting device includes: a substrate; an auxiliary layer and a quantum dot layer that are arranged in sequence on one side of the substrate; the auxiliary layer has a first group and a second group, the first group and a surface group of the substrate are bound with each other through a chemical reaction, the second group and ligands of quantum dots in the quantum dot layer are bound with each other through a chemical reaction, and a binding force between the auxiliary layer and the substrate is smaller than a binding force between the quantum dots and the auxiliary layer.

### TECHNICAL FIELD

The present disclosure relates to the field of display technology, and specifically to a light-emitting device and a preparation method thereof, a display panel, and a display device.

### BACKGROUND

Semiconductor quantum dots are an important fluorescent nanomaterial, and the use of quantum dots as a light-emitting layer material for flat panel lighting and optoelectronic display applications is receiving increasing attention. Up to now, in terms of device performance, the external quantum efficiency (EQE) of Quantum Dot Light-Emitting Diodes (QLED) has reached more than 20%. The patterning process of the light-emitting layer quantum dots is a key step in determining full-color, high-resolution QLED devices. At present, the patterning process of quantum dots has been realized by transfer printing, inkjet printing, photolithography and the like.

### SUMMARY

The present disclosure provides a light-emitting device and a preparation method thereof, a display panel, and a display device.

In a first aspect, the present disclosure provides a light-emitting device, including:
a substrate; and
an auxiliary layer and a quantum dot layer that are arranged in sequence on one side of the substrate;
wherein the auxiliary layer has a first group and a second group, the first group and a surface group of the substrate may be bound with each other through a chemical reaction, and the second group and ligands of quantum dots in the quantum dot layer may be bound with each other through a chemical reaction, and a binding force between the auxiliary layer and the substrate is smaller than a binding force between the quantum dots and the auxiliary layer.

Optionally, the second group and the ligands of the quantum dots in the quantum dot layer are bound with each other through ligand exchange or cross-linking reaction.

Optionally, the first group is arranged close to the substrate, and the second group is arranged close to the quantum dot layer.

Optionally, the auxiliary layer is made of an organic material and has a thickness of 0.1 nm −1 nm.

Optionally, the auxiliary layer includes at least one of compounds represented by structural formula (1) and structural formula (2),

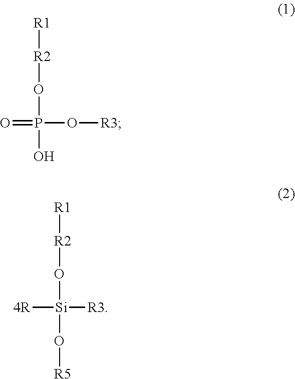

Optionally, R1 includes at least one of a benzene ring-conjugated double bond, a carbon-oxygen double bond, a carbon-carbon double bond, a carbon-nitrogen double bond, hydroxyl, carboxyl, and mercapto, R2 is a carbon chain with a saturated or unsaturated bond, R3 includes at least one of alkoxy, acetoxy and halogen, R4 includes at least one of alkoxy, acetoxy and halogen, and R5 includes at least one of alkoxy, acetoxy and halogen.

Optionally, the auxiliary layer includes:

at least one of 3-mercaptopropyltrimethoxysilane, 3-mercaptopropyl triethoxysilane, 3-mercaptopropylmethyldimethoxysilane, 3-mercaptopropylmethyldiethoxysilane, mercaptopropylsilane, 3-mercaptopropyltrimethylsilane and bis-[3-(triethoxysilyl)propyl]-tetrasulfide.

Optionally, the light-emitting device has a plurality of pixels arranged in an array, each of the pixels includes a first sub-pixel and a second sub-pixel, a spacer structure is provided on the substrate, and a minimum area enclosed by adjacent spacer structures constitutes a sub-pixel; and the quantum dot layer includes a first quantum dot and a second quantum dot, the first quantum dot is arranged in the first sub-pixel, and the second quantum dot is arranged in the second sub-pixel, and the first quantum dot and the second quantum dot have different emission wavelengths.

Optionally, the substrate further includes a first electrode and a first carrier transport layer that are laminated one on another, and the first carrier transport layer is arranged closer to the auxiliary layer.

Optionally, the substrate further includes a backplate, the backplate includes a light-emitting unit, and light having a first wavelength band emitted by the light-emitting unit, after passing through the first quantum dot, becomes light having a second wavelength band to be emitted: the light having the first wavelength band emitted by the light-emitting unit, after passing through the second quantum dot, becomes light having a third wavelength band; and the binding force between the auxiliary layer and the substrate is greater than a binding force between the auxiliary layer and the spacer structure.

Optionally, each of the pixels further includes a third sub-pixel, the quantum dot layer is correspondingly provided with a third quantum dot, the third quantum dot is arranged in the third sub-pixel, and the first quantum dot, the second quantum dot and the third quantum dot have different emission wavelengths.

Optionally, the binding force between the auxiliary layer and the substrate is greater than a binding force between the auxiliary layer and the spacer structure.

Optionally, the light-emitting device further includes:
a second carrier transport layer arranged on the side of the quantum dot layer away from the substrate; and
a second electrode arranged on the side of the second carrier transport layer away from the substrate.

In a second aspect, the present disclosure provides a preparation method of a light-emitting device, comprising:
providing a substrate; and
forming an auxiliary layer and a quantum dot layer in sequence on one side of the substrate.

Optionally, the auxiliary layer has a first group and a second group, the first group and a surface group of the substrate may be bound with each other through a chemical reaction, the second group and ligands of quantum dots in the quantum dot layer may be bound with each other through a chemical reaction, and a binding force between the auxiliary layer and the substrate is smaller than a binding force between the quantum dots and the auxiliary layer.

Optionally, the second group and the ligands of the quantum dots in the quantum dot layer are bound with each other through a ligand exchange or cross-linking reaction.

Optionally, the forming the auxiliary layer and the quantum dot layer in sequence on one side of the substrate includes:

forming an auxiliary layer on one side of the substrate; and forming a plurality of pixels arranged in an array on the auxiliary layer.

Optionally, each of the pixels includes a first sub-pixel and a second sub-pixel, the quantum dot layer includes a first quantum dot and a second quantum dot, the first quantum dot is formed in the first sub-pixel, and the second quantum dot is formed in the second sub-pixel, a minimum area enclosed by adjacent spacer structures on the substrate constitutes a sub-pixel, and the first quantum dot and the second quantum dot have different emission wavelengths.

Optionally, each of the pixels further includes a third sub-pixel, the quantum dot layer is correspondingly provided with a third quantum dot, the third quantum dot is formed in the third sub-pixel, and the first quantum dot, the second quantum dot and the third quantum dot have different emission wavelengths.

Optionally, the binding force between the auxiliary layer and the substrate is greater than a binding force between the auxiliary layer and the spacer structure.

In a third aspect, the present disclosure provides a display panel including the light-emitting device described in the above embodiments.

In a fourth aspect, the present disclosure provides a display device including the display panel described in the above embodiments.

### BRIEF DESCRIPTION OF THE DRAWINGS

FIG. 1 is a schematic view showing a structure of a light-emitting device according to an embodiment of the present disclosure.

FIG. 2 is a schematic view showing a structure of a light-emitting device according to another embodiment of the present disclosure.

FIG. 3 is a schematic view showing a structure of a light-emitting device according to another embodiment of the present disclosure.

FIG. 4 is a schematic view showing a structure of a light-emitting device according to another embodiment of the present disclosure.

FIG. 5 is a schematic view showing a structure of a light-emitting device according to another embodiment of the present disclosure.

FIG. 6 is a schematic view showing a structure of a light-emitting device according to another embodiment of the present disclosure.

FIG. 7 is a schematic view showing the surface of the substrate with surface groups.

FIG. 8 is a schematic flowchart showing the formation of an auxiliary layer on a substrate with surface groups.

FIG. 9 is another schematic flowchart showing the formation of an auxiliary layer on a substrate with surface groups.

FIG. 10 is a schematic view showing cross-linking of the ligand on the quantum dots with the auxiliary layer.

FIG. 11 is a schematic flowchart of forming different quantum dot layers in the pixel area.

FIG. 12 is a schematic flowchart of forming different quantum dot layers in the pixel area of the blue light backplate.

FIG. 13 is a schematic flowchart of forming different quantum dot layers in the pixel area of the white light backplate.

FIG. 14 is another schematic flowchart of forming different quantum dot layers in the pixel area of the blue light backplate.

### DETAILED DESCRIPTION

The technical solutions of the present disclosure will be clearly and completely described below with reference to the drawings in the present disclosure. Obviously, the described embodiments are part of the embodiments of the present disclosure, but not all of the embodiments. Based on the embodiments in the present disclosure, all other embodiments obtained by those of ordinary skill in the art without creative efforts shall fall within the protection scope of the present disclosure.

The terms “first”, “second”, etc. in the specification and claims of present disclosure are used to distinguish similar objects and are not intended to describe a particular order or sequence. It should be understood that data so used may be interchanged under appropriate circumstances so that embodiments of the present disclosure may be practiced in sequences other than those illustrated or described herein.

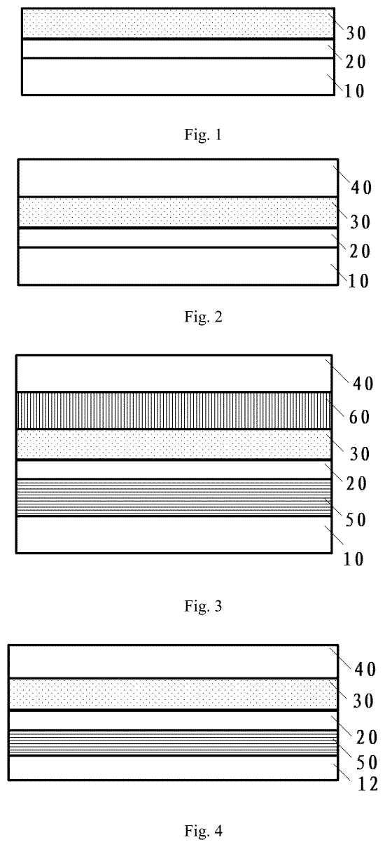

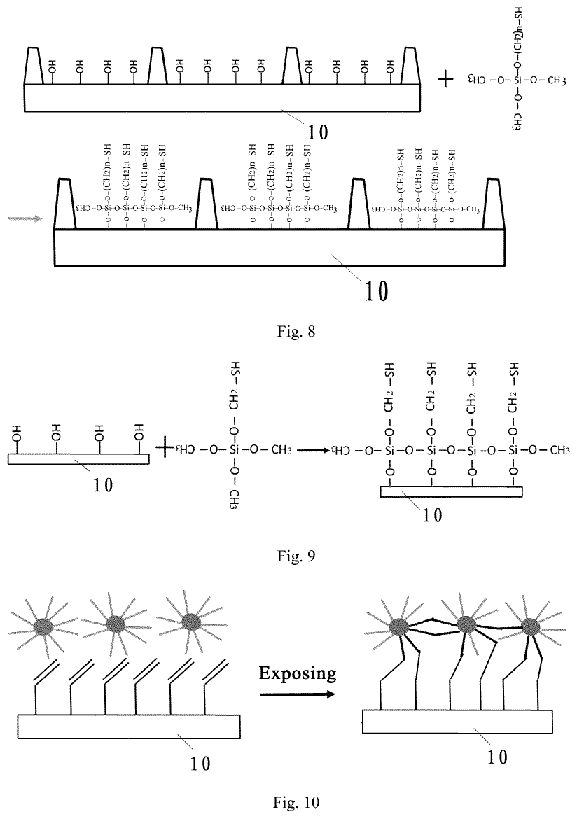

The light-emitting device provided by the present disclosure will be described in detail below with reference to FIG. 1 to FIG. 14 through specific embodiments and application scenarios thereof. In the drawings, the thickness of layers, films, panels, regions, etc. are exaggerated for clarity. Exemplary embodiments are described herein with reference to cross-sectional views that are schematic view of idealized embodiments. As such, deviations from the shapes of the drawings and the result are to be expected, for example, as manufacturing techniques and/or tolerances. Thus, the embodiments described herein should not be construed as being limited to the specific shapes of regions as shown herein, but rather include deviations in shapes resulting from, for example, manufacturing. For example, a region illustrated or described as flat may typically have rough and/or nonlinear features. Furthermore, the sharp corners as illustrated may be rounded. Thus, the regions illustrated in the figures are schematic in nature and their shapes are not intended to illustrate the precise shape of a region and are not intended to limit the scope of the present claims.

As used herein, the term “and/or” includes any and all combinations of one or more of the associated listed items. It will be further understood that the terms “comprise” or “include” when used in this specification indicate the presence of the stated feature, region, integer, step, operation, element, and/or component. However, the presence or addition of one or more other features, regions, integers, steps, operations, elements, components and/or combinations thereof is not excluded.

Usually, the patterning of electronic materials (quantum dots) is realized by photolithography. During the development process in the photolithography process, some quantum dots that should have been developed will remain in the pixel area, resulting in color mixing problems.

As shown in FIG. 1 to FIG. 6, the light-emitting device of the present disclosure includes: a substrate 10; an auxiliary layer 20 and a quantum dot layer 30 that are arranged in sequence on one side of the substrate 10, the auxiliary layer 20 has a first group and a second group, the first group and a surface group of the substrate 10 may be bound with each other through a chemical reaction, the second group and ligands of quantum dots in the quantum dot layer 30 may be bound with each other through a chemical reaction, a binding force between the auxiliary layer 20 and the substrate 10 is smaller than a binding force between the quantum dots and the auxiliary layer 20. In the light-emitting device of the present disclosure, the auxiliary layer 20 is arranged between the substrate 10 and the quantum dot layer 30, the first group and a surface group of the substrate 10 may be bound with each other through a chemical reaction, the second group and ligands of quantum dots in the quantum dot layer 30 may be bound with each other through a chemical reaction, the quantum dots in the quantum dot layer 30 may be stably bound to the auxiliary layer 20. During the preparation process, the binding of the quantum dots in the pixel area through the auxiliary layer is stable and firm, and the quantum dots that are not bound to the auxiliary layer are easily removed. Since the binding force between the auxiliary layer 20 and the substrate 10 is smaller than the binding force between the quantum dots and the auxiliary layer 20, when the auxiliary layer is used as a sacrificial layer, it is easy to be rinsed away, and the quantum dots remained on the auxiliary layer are taken away incidentally and are not easy to remain in the pixel area, this may ensure the purity of the quantum dots in the pixel area, avoid other colors of quantum dots remaining in the pixel area, avoid the problem of mixing of light-emitting devices, improving the light-emitting effect, and is conducive to improving the performance of the full-color QLED.

The light-emitting device may be an inverted structure, an upright structure, a top emission device and a bottom emission device. The substrate 10 may include the first electrode 12, and the second electrode 40 may be arranged on the side of the quantum dot layer 30 away from the auxiliary layer 20, for example, the first electrode 12 may be a cathode, the second electrode 40 may be an anode. By applying a voltage between the first electrode 12 and the second electrode 40, the quantum dots in the quantum dot layer 30 may emit light.

The substrate 10 may be a backplate, and the backplate includes a light-emitting unit, and the light emitted by the light-emitting unit may emit light having a desired wavelength through the conversion of the quantum dots in the quantum dot layer 30, that is, the quantum dots in the quantum dot layer 30 may function as a wavelength conversion layer. For example, the light-emitting unit in the backplate may emit blue light, and the quantum dots in the quantum dot layer 30 may include the first quantum dot and the second quantum dot. After passing through the first quantum dot, the blue light may be converted into the second wavelength band of light (such as red light) to convert the blue light into red light. After passing through the second quantum dot, blue light may be converted into the third wavelength band of light (such as green light). Full-color display may be achieved through the cooperation of red, blue and green sub-pixels.

The substrate 10 further includes a first electrode and a first carrier transport layer 50 that are laminated one on another, and the first carrier transport layer 50 is arranged closer to the auxiliary layer 20. The surface on the side of the first carrier transport layer 50 close to the auxiliary layer 20 has surface groups, the first group of the auxiliary layer 20 and the surface groups of the first carrier transport layer 50 may be bound with each other through a chemical reaction, the second group of the auxiliary layer 20 and the ligands of the quantum dots in the quantum dot layer 30 may be bound with each other through a chemical reaction, so that the quantum dots in the quantum dot layer 30 may be stably bound to the auxiliary layer 20, the binding force between the auxiliary layer 20 and the first carrier transport layer 50 is smaller than the binding force between the quantum dots and the auxiliary layer 20. During the preparation process, the binding of the quantum dots in the pixel area through the auxiliary layer is stable and firm, and the quantum dots that are not bound to the auxiliary layer are easily removed. Since the binding force between the auxiliary layer 20 and the first carrier transport layer 50 is smaller than the binding force between the quantum dots and the auxiliary layer 20, when the auxiliary layer 20 is used as a sacrificial layer, it is easy to be rinsed away, and the quantum dots remained on the auxiliary layer are taken away incidentally, and are not easy to remain in the pixel area, and avoid other colors of quantum dots remaining in the pixel area.

In the process of preparing the light-emitting device, quantum dots may be printed in the pixel area of the auxiliary layer 20 to form the quantum dot layer 30. In the preparation process, the substrate 10 may include the first electrode 12, the first electrode 12 may be disposed on the substrate, the substrate may be glass, and the glass with the first electrode 12 may be conductive glass, the first carrier transport layer 50 may be formed on the first electrode 12. The first electrode 12 may be a cathode, the first carrier transport layer 50 may be an electron transport layer. The electron transport layer may include at least one of ZnO, ZnMgO and TiO₂ materials, for example, the electron transport layer may include ZnO, the first carrier transport layer 50 may have surface groups, and the surface groups may be hydroxyl groups. The auxiliary layer 20 may be formed on the first carrier transport layer, the auxiliary layer 20 may be a monomolecular layer, and the auxiliary layer 20 has a second group, the second group is a group that may cross-link with the ligand of the quantum dot. In the process of preparing light-emitting devices, by introducing an auxiliary layer, this method may be used to print Active-Matrix Quantum dot Light-Emitting Diodes (AMQLEDs), which may improve the morphology of quantum dot films, and the color mixing problem may be effectively solved in AMQLED using photolithography.

As shown in FIG. 7 to FIG. 9, an auxiliary layer 20 may be formed on the first electrode or the electron transport layer on the surface of the first electrode, the auxiliary layer 20 may be a monomolecular layer, and the auxiliary layer 20 may have a silane reagent with mercapto groups, for example, the silane reagent may be 3-mercaptopropyltrimethoxysilane. Taking 3-mercaptopropyltrimethoxysilane monomolecular layer as an example, an ethanol solution of 3-mercaptopropyltrimethoxysilane (3-mercaptopropyltrimethoxysilane 0.5 mL, ethanol 4.5 mL) is prepared, and a small amount of ammonia water (0.1 mL) is added. 90 uL of the above solution is added dropwise onto the above conductive glass, spin-coated to form a film, rotated at 1000-4000 rpm, and left at room temperature for 1-2 h. Then the above conductive glass is rinsed with ultra-dry absolute ethanol for 2-3 times. This step may be done in the air, which may get rid of the dependence on the expensive glove box. In this method, taking 3-mercaptopropyltrimethoxysilane as an example, by controlling the concentration and the spin coating speed of the silane solution, a dense silane-coupled silicon oxide film is formed on the upper film layer. In addition, silane reagents with mercapto groups may be selected from: at least one of 3-mercaptopropyltrimethoxysilane, 3-mercaptopropyl triethoxysilane, 3-mercaptopropylmethyldimethoxysilane, 3-mercaptopropylmethyldiethoxysilane, mercaptopropylsilane, 3-mercaptopropyltrimethylsilane and bis-[3-(triethoxysilyl)propyl]-tetrasulfide.

Graphical quantum dots may be printed on the auxiliary layer 20, quantum dots may be printed in the pixel area of the auxiliary layer 20, and the quantum dots may be fixed on the auxiliary layer 20 through cross-linking or ligand exchange. After the quantum dots are printed on the corresponding position, the leaked second groups in the monomolecular layer, such as mercapto groups, may chemically react with the ligands of the quantum dots, so that the quantum dots are fixed on the auxiliary layer 20, which may prevent the quantum dots from climbing, thereby increasing the flatness of the quantum dot layer, and optimizing the film morphology of the printed quantum dot.

In the light-emitting device of the present disclosure, the auxiliary layer 20 is arranged between the substrate 10 and the quantum dot layer 30, the auxiliary layer 20 has a second group, and the second group is bound with the ligands of the quantum dots in the quantum dot layer 30 through chemical bonds, and the quantum dots in the quantum dot layer 30 may be stable and firm through the auxiliary layer 20. During the preparation process, the binding of the quantum dots in the pixel area through the auxiliary layer 20 is stable and firm.

As shown in FIG. 11, the preparation process of the light-emitting device may be as follows:
forming an electron transport layer on the first electrode on the conductive glass, in which the electron transport layer may be a zinc oxide-based nanoparticle film or a zinc oxide film, and the surface of the electron transport layer has surface groups:
forming the auxiliary layer 20 on the surface of the electron transport layer, in which the ethanol solution of silane reagent (0.5 mL of silane reagent, 4.5 mL of ethanol) was prepared, the structural formula of the silane reagent may be shown in structural formula (3), and a small amount of ammonia water (0.1 mL) was added, 90 uL of the above solution was added dropwise onto the electron transport layer, spin-coated to form a film, and left at room temperature for 1-2 h, the surface groups of the electron transport layer was reacted with the silane reagent chemically, then the above conductive glass was rinsed with ultra-dry absolute ethanol, the quantum dots was patterned by setting the auxiliary layer without dry etching, but only with cleaning, which reduces the damage to the film layer:

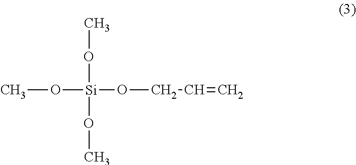

patterning quantum dots (QD), in which the auxiliary layer 20 has been formed on the electron transport layer, and the surface of the auxiliary layer 20 has the second group, which may include double bond cross-linking groups, such as hydroxyl and mercapto groups. The pixel region of the auxiliary layer is coated with the first quantum dot (such as red quantum dot), the ligands of the deposited first quantum dots have a third group, the third group may cross-link with the second group, and the third group may include the double bond, the triple bond, the hydroxyl group, the carboxyl group, etc. The corresponding pixel area is exposed to the first light, so that the ligand of the first quantum dot and the second group of the auxiliary layer 20 may undergo a cross-linking reaction. The first quantum dot in the unexposed part are eluted by developing, and the first quantum dot layer 31 is formed in the corresponding pixel area, but there will be some remaining first quantum dots in the unexposed area. Then, deep ultraviolet (wavelength from 200 nm to 350 nm) light (second light) may be used for flood exposure to dissociate the monomolecular layer from the lower film layer. The monomolecular layer is then developed to eliminate the remaining first quantum dots and prevent color mixing.

The above steps may be repeated to form patterned second quantum dots (such as green light quantum dots) and patterned third quantum dots (such as blue light quantum dots) in corresponding pixel areas, respectively. Further, the patterned second quantum dot layer 32 and the patterned third quantum dot layer 33 are formed in the corresponding pixel area, which may remove other quantum dots remaining in the non-exposed area, prevent color mixing, and form a full-color QLED: the patterning sequence of red light quantum dots, green light quantum dots and blue light quantum dots may also be adjusted as required.

The hole transport layer, the hole injection layer and the second electrode may also be formed on the quantum dot layer in sequence, and finally a quantum dot light-emitting device is prepared by encapsulation. During the preparation process, other quantum dots remaining in the non-exposed area may be removed by forming the auxiliary layer 20, and the quantum dots that are not bound to the auxiliary layer 20 may be easily removed, and not easy to remain in the pixel area, this may ensure the purity of the quantum dots in the pixel area, avoid other colors of quantum dots remaining in the pixel area, avoid the problem of mixing of light-emitting devices, thereby improving the luminous effect, and is conducive to improving the performance of the full-color QLED. The preparation process does not need to use photoresist lithography, avoids the photolithography solvent damaging the quantum dots, and avoids the hydroxide ions in the alkaline developer solution destroying the coordination of surface ligands and quantum dot dangling bonds, prevent surface defect sites of quantum dots from being re-exposed to ensure device efficiency. In addition, the auxiliary layer 20 is bound between the substrate/the first carrier transport layer and the quantum dot layer, which may adjust the carrier transport rate to a certain extent, and further improve the performance of the full-color QLED.

The second group and the ligands of the quantum dots in the quantum dot layer 30 may combine with each other through ligand exchange or cross-linking reaction. Wherein, the first group is arranged close to the substrate 10, so that the first group and the surface group of the substrate 10 are bound by chemical reaction. The second group is arranged close to the quantum dot layer 30, so that the second group and the ligands of the quantum dots in the quantum dot layer 30 are bound by chemical reaction. For example, the surface groups may include hydroxyl or carboxyl, the first group may include hydroxyl, carboxyl or double bonds. The hydroxyl group may react with a carboxyl group or a double bond, so that the first group and the surface group may be bound by chemical bonds, and the substrate 10 and the auxiliary layer 20 are stably and firmly bound together.

Optionally, the ligands of the quantum dots may have a third group, and the second group and the third group may be bound by chemical bonds. For example, the third group may include at least one of amino group, hydroxyl group and carboxyl group, and the second group may include at least one of mercapto group, amino group, hydroxyl group, carboxyl group and double bond. The hydroxyl group may react with a carboxyl group or a double bond, and the second group and the third group may undergo a chemical reaction, so that the second group and the third group may be bound by a chemical bond. The auxiliary layer 20 and the ligands of the quantum dots in the quantum dot layer 30 are firmly bound through chemical bonds, and the quantum dots in the quantum dot layer 30 may be stabilized by the auxiliary layer 20.

Optionally, the auxiliary layer 20 may be made of an organic material, and have a thickness of 0.1 to 1 nm, for example, the thickness of the auxiliary layer 20 may be 0.5 nm, which is small.

In an embodiment of the present disclosure, the auxiliary layer 20 may include at least one of compounds represented by structural formula (1) and structural formula (2), the structural formula (1) and structural formula (2) are as follow:

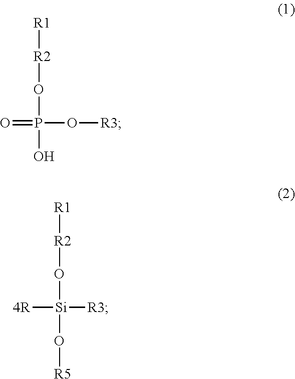

wherein, R1 may include at least one of benzene ring-conjugated double bond, carbon-oxygen double bond, carbon-carbon double bond, carbon-nitrogen double bond, hydroxyl, carboxyl, and mercapto, R2 may be a carbon chain with saturated or unsaturated bonds, R3 may include at least one of alkoxy, acetoxy and halogen, R4 may include at least one of alkoxy, acetoxy and halogen, R5 may include at least one of alkoxy, acetoxy and halogen.

In some embodiments, the auxiliary layer 20 may include: at least one of 3-mercaptopropyltrimethoxysilane, 3-mercaptopropyl triethoxysilane, 3-mercaptopropylmethyldimethoxysilane, 3-mercaptopropylmethyldiethoxysilane, mercaptopropylsilane, 3-mercaptopropyltrimethylsilane and bis-[3-(triethoxysilyl)propyl]-tetrasulfide, for example, the auxiliary layer 20 may include: 3-mercaptopropyltrimethoxysilane, the mercapto group may form a coordination bond with the surface of the quantum dot, and the surface defect of the quantum dot may be improved by forming the coordination bond. The mercapto group may also be used as a second group, and the ligand of the quantum dot may be bound with the second group through a chemical bond. A stable binding is made between the quantum dots and the auxiliary layer 20.

In some embodiments, as shown in FIG. 6, the light-emitting device may have a plurality of pixels arranged in an array, each of the pixels includes a first sub-pixel 101 and a second sub-pixel 102, and a spacer structure 11 is provided on substrate 10, the minimum area enclosed by adjacent spacer structures may constitute a sub-pixel. The quantum dot layer 30 may include a first quantum dot and a second quantum dot, the first quantum dot is arranged in the first sub-pixel 101, and the second quantum dot is arranged in the second sub-pixel 102, the first quantum dot and the second quantum dot may have different emission wavelengths, for example, the first quantum dot may emit red light, and the second quantum dot may emit green light.

Different sub-pixels may be arranged in corresponding pixel areas, for example, the auxiliary layer 20 may have a first pixel area and a second pixel area, and the first sub-pixel 101 is correspondingly arranged in the first pixel area, the second sub-pixels 102 are correspondingly arranged in the second pixel area, and the first quantum dots may be arranged in the first pixel area to form the first quantum dot layer 31, the second quantum dots may be arranged in the second pixel region to form the second quantum dot layer 32.

In the embodiment of the present disclosure, the substrate 10 further includes a backplate, and the backplate may include a light-emitting unit, and light having a first wavelength band emitted by the light-emitting unit, after passing through the first quantum dots, becomes light having a second wavelength band to be emitted: light having the first wavelength band emitted by the light-emitting unit, after passing through the second quantum dot, becomes light having a third wavelength band.

The light emitted by the backplate may emit light of the desired wavelength through the conversion of the quantum dots in the quantum dot layer 30, the quantum dots in the quantum dot layer 30 may be used as light conversion quantum dots, and the quantum dots convert the light emitted by the backplate into light with a desired wavelength. For example, the backplate may emit blue light, and the quantum dots in the quantum dot layer 30 may include the first quantum dots and the second quantum dots. After the blue light passing through the first quantum dot, the first quantum dot converts the blue light into red light. After the blue light passing through the second quantum dot, the second quantum dot converts the blue light into green light, and the backplate itself emits blue light, and a full-color display may be realized by the cooperation of red light, blue light and green light.

In some embodiments, as shown in FIG. 6, each of the pixels may further include a third sub-pixel 103, and the quantum dot layer 30 is correspondingly provided with third quantum dots, and the third quantum dots are arranged in the third sub-pixel 103. The first quantum dot, the second quantum dot and the third quantum dot have different emission wavelengths, for example, the first quantum dot may emit red light, the second quantum dot may emit green light, and the third quantum dot may emit blue light. The auxiliary layer 20 may have a third pixel area, the third sub-pixels 103 in each pixel may be correspondingly provided with a third pixel area, and the third quantum dots may be arranged in the third pixel area to form the third quantum dot layer 33. Taking an inverted device as an example, the substrate 10 may include the first electrode 12 and the electron transport layer 52 that are laminated one on another, and the auxiliary layer 20 is arranged on the side of the electron transport layer 52 away from the first electrode 12. The spacer structure 11 on the substrate 10 may space the first electrode 12, the electron transport layer 52 and the organic layer apart, and different quantum dots may be separated by the spacer structure 11 to form different sub-pixels.

In some embodiments, the light emitted by the backplate may emit light having a desired wavelength through the conversion of the quantum dots in the quantum dot layer 30, the quantum dots in the quantum dot layer 30 may be used as light conversion quantum dots, and the quantum dots convert the light emitted by the backplate into light having a desired wavelength. For example, the backplate may emit white light, and the quantum dots in the quantum dot layer 30 may include the first quantum dots, the second quantum dots, and the third quantum dot. After the white light passing through the first quantum dot, the first quantum dot emits red light. After the white light passing through the second quantum dot, the second quantum dot emits green light. After the white light passing through the first quantum dot, the first quantum dot emits blue light, and a full-color display may be realized by the cooperation of red light, blue light and green light.

In the embodiments of the present disclosure, the binding force between the auxiliary layer 20 and the substrate 10 is greater than the binding force between the auxiliary layer 20 and the spacer structure 11. During the preparation, since the binding force between the auxiliary layer 20 and the substrate 10 is greater than the binding force between the auxiliary layer 20 and the spacer structure 11, and the binding force between the auxiliary layer 20 and the substrate 10 is smaller than the binding force between the quantum dots and the auxiliary layer 20, when the auxiliary layer 20 is used as a sacrificial layer, it is easy to be rinsed away, and the quantum dots remained on the auxiliary layer are taken away incidentally, and are not easy to remain in the pixel area, this may ensure the purity of the quantum dots in the pixel area, avoid other colors of quantum dots remaining in the pixel area, avoid the problem of color mixing in the light-emitting device.

In an embodiment of the present disclosure, as shown in FIG. 3, the substrate 10 may include a first electrode, and the light-emitting device may further include:

the second carrier transport layer 60 and the second electrode 40, the second carrier transport layer 60 is arranged on the side of the quantum dot layer 30 away from the substrate 10, and the second electrode 40 is arranged on the side of the second carrier transport layer 60 away from the substrate 10. The second carrier transport layer 60 is beneficial to improve the transport efficiency of carriers, and by applying a voltage between the first electrode and the second electrode 40, the quantum dots in the quantum dot layer 30 may be made to emit light.

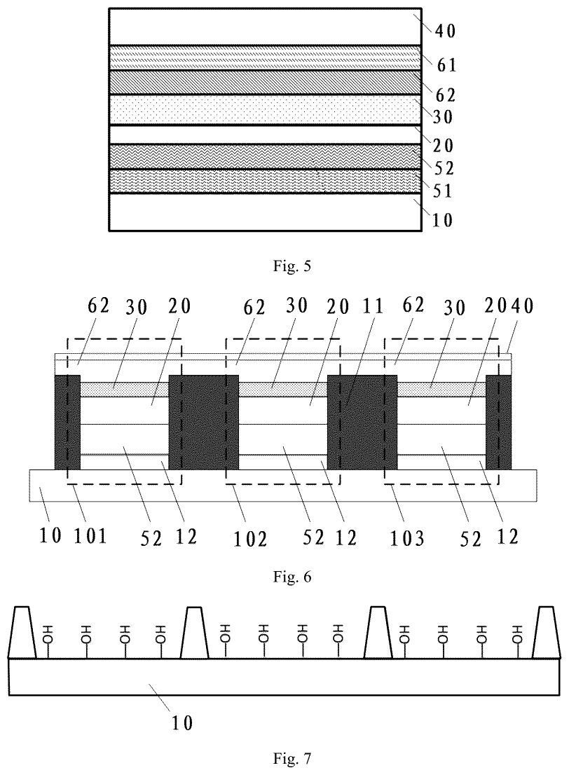

As shown in FIG. 3 and FIG. 5, the first electrode may be a cathode, which may be arranged on a glass substrate, and the first carrier transport layer 50 may include at least one of the electron injection layer 51 and the electron transport layer 52. The first carrier transport layer 50 may include the electron injection layer 51 and the electron transport layer 52, and the electron injection layer 51 is arranged close to the first electrode. The electron transport layer may include at least one of ZnO, ZnMgO and TiO₂ materials, for example, the electron transport layer may include ZnO, and the surface on the side of the electron transport layer 52 away from the first electrode may have surface groups, such as hydroxyl groups, so that the surface groups and the first groups in the auxiliary layer 20 are bound by chemical bonds. The second electrode may be an anode, the second carrier transport layer 60 may include at least one of the hole injection layer 61 and the hole transport layer 62, the second carrier transport layer 60 may include the hole injection layer 61 and the hole transport layer 62, and the hole injection layer 61 is arranged close to the second electrode.

Optionally, the first electrode may be an anode, the first carrier transport layer may include at least one of the hole injection layer and the hole transport layer, the first carrier transport layer may include the hole injection layer and the hole transport layer, and the hole injection layer is arranged close to the first electrode. The second electrode may be an cathode, the cathode may be arranged on the glass substrate, the second carrier transport layer may include at least one of the electron injection layer and the electron transport layer, the second carrier transport layer may include both the electron injection layer and the electron transport layer, and the electron injection layer is arranged close to the second electrode.

The present disclosure provides a method for preparing a light-emitting device, comprising:

providing the substrate 10, the substrate 10 comprising the first electrode or backplate, wherein the backplate may comprise a light-emitting unit; and forming the auxiliary layer 20 and the quantum dot layer 30 in sequence on one side of the substrate:

wherein the auxiliary layer 20 has a first group and a second group, the first group and the surface group of the substrate 10 may be bound with each other through a chemical reaction, and the second group and the ligands of the quantum dots in the quantum dot layer 30 may be bound with each other through a chemical reaction. The binding force between the auxiliary layer 20 and the substrate 10 is smaller than the binding force between the quantum dots and the auxiliary layer 20. The auxiliary layer 20 is arranged between the substrate 10 and the quantum dot layer 30, the second group and the ligands of the quantum dots in the quantum dot layer 30 may be bound with each other through a chemical reaction, such that the quantum dots in the quantum dot layer 30 may be stably bound to the auxiliary layer 20. During the preparation process, the binding of the quantum dots in the pixel area through the auxiliary layer is stable and firm, and the quantum dots that are not bound to the auxiliary layer are easily removed. Since the binding force between the auxiliary layer 20 and the substrate 10 is smaller than the binding force between the quantum dots and the auxiliary layer 20, when the auxiliary layer is used as a sacrificial layer, it is easy to be rinsed away, and the quantum dots remained on the auxiliary layer are taken away incidentally, and are not easy to remain in the pixel area, this may ensure the purity of the quantum dots in the pixel area, avoid other colors of quantum dots remaining in the pixel area, avoid the problem of mixing of light-emitting devices, improving the luminous effect, and is conducive to improving the performance of the full-color QLED.

In some embodiments, the second group and the ligands of the quantum dots in the quantum dot layer 30 may bind with each other through ligand exchange or cross-linking reaction. Wherein, the first group may be arranged close to the substrate 10, so that the first group and the surface group of the substrate 10 are bound by a chemical reaction. The second group may be arranged close to the quantum dot layer 30, so that the second group and the ligands of the quantum dots in the quantum dot layer 30 are bound by a chemical reaction.

The forming the auxiliary layer 20 and the quantum dot layer 30 in sequence on one side of the substrate 10 may include:
forming an auxiliary layer 20 on one side of the substrate 10; and
forming a plurality of pixels arranged in an array on the auxiliary layer 20:
wherein as shown in FIG. 6, each of the pixels includes a first sub-pixel 101 and a second sub-pixel 102, the quantum dot layer includes a first quantum dot and a second quantum dot, the first quantum dot is formed in the first sub-pixel 101, and the second quantum dot is formed in the second sub-pixel 102, a minimum area enclosed by adjacent spacer structures 11 on the substrate 10 forms a sub-pixel, and the first quantum dot and the second quantum dot have different emission wavelengths. For example, the first quantum dot may emit red light, and the second quantum dot may emit green light. Different sub-pixels may be formed in corresponding pixel areas, for example, the auxiliary layer 20 may have a first pixel area and a second pixel area, and the first sub-pixel 101 is correspondingly formed in the first pixel area, the second sub-pixel 102 is correspondingly formed in the second pixel area, the first quantum dots may be formed in the first pixel area to form the first quantum dot layer 31, and the second quantum dots may be formed in the second pixel area to form the second quantum dot layer 32.

In the light-emitting device prepared by the above method, the auxiliary layer 20 is arranged between the substrate 10 and the quantum dot layer 30, the auxiliary layer 20 has a second group, and the second group is bound with the ligands of the quantum dots in the quantum dot layer 30 through chemical bonds, and the quantum dots in the quantum dot layer 30 may be stable and firm through the auxiliary layer 20. During the preparation process, the binding of the quantum dots in the pixel area through the auxiliary layer 20 is stable and firm, and the quantum dots that are not bound to the auxiliary layer 20 are easily removed, and are not easy to remain in the pixel area, this may ensure the purity of the quantum dots in the pixel area, and avoid other colors of quantum dots remaining in the pixel area.

The substrate may include a backplate, and the backplate may include a light-emitting unit, and light having a first wavelength band emitted by the light-emitting unit, after passing through the first quantum dots, becomes light having a second wavelength band to be emitted: the light having the first wavelength band emitted by the light-emitting unit, after passing through the second quantum dot, becomes light having a third wavelength band. For example, the light-emitting unit may emit blue light, after the blue light passing through the first quantum dot, the first quantum dot converts the blue light into red light. After the blue light passing through the second quantum dot, the second quantum dot converts the blue light into green light, and the backplate itself emits blue light, and a full-color display may be realized by the cooperation of red light, blue light and green light. As shown in FIG. 4, the substrate 10 may further include a first electrode 12 and a first carrier transport layer 50 that are laminated one on another, and the first carrier transport layer 50 is arranged closer to the auxiliary layer 20. In the preparation process, before the auxiliary layer 20 is formed, the first electrode 12 and the first carrier transport layer 50 may be sequentially formed on the substrate. Then the auxiliary layer 20 is formed on the first carrier transport layer 50, the quantum dot layer 30 is formed on the auxiliary layer 20, and a second electrode 40 is formed on the quantum dot layer 30. By applying a voltage between the first electrode 12 and the second electrode 40, the quantum dots in the quantum dot layer 30 may be made to emit light. The first carrier transport layer 50 may include at least one of the electron injection layer 51 and the electron transport layer 52, for example, the first carrier transport layer 50 may include the electron injection layer 51 and the electron transport layer 52, and the electron injection layer 51 is arranged close to the first electrode.

Before forming the second electrode 40, the method may further include: the second carrier transport layer 60 may be formed on the side of the quantum dot layer 30 away from the substrate 10, and then the second electrode 40 may be formed on the side of the second carrier transport layer 60 away from the quantum dot layer 30. The second carrier transport layer 60 is beneficial to improve the transport efficiency of carriers, and by applying a voltage between the first electrode and the second electrode 40, the quantum dots in the quantum dot layer 30 may be made to emit light. The second carrier transport layer 60 may include at least one of the hole injection layer 61 and the hole transport layer 62, for example, the second carrier transport layer 60 may include the hole injection layer 61 and the hole transport layer 62, and the hole injection layer 61 may be arranged close to the second electrode 40.

In some embodiments, each of the pixels may further include a third sub-pixel 103, the quantum dot layer is correspondingly provided with a third quantum dot, and the third quantum dots are formed in the third sub-pixel 103. The first quantum dot, the second quantum dot and the third quantum dot have different emission wavelengths. For example, the auxiliary layer 20 may have a third pixel area, the third sub-pixel 103 may be correspondingly formed in the third pixel area, and the third quantum dot may be formed in the third pixel area to form the third quantum dot layer 31. The first quantum dot may emit red light, the second quantum dot may emit green light, and the third quantum dot may emit blue light, and a full-color display may be realized by the cooperation of red light, blue light and green light.

In the embodiments of the present disclosure, the bonding force between the auxiliary layer 20 and the substrate 10 is greater than the binding force between the auxiliary layer 20 and the spacer structure 11. During the preparation process, the auxiliary layer 20 is arranged between the substrate 10 and the quantum dot layer 30, the binding of the quantum dots in the pixel area through the auxiliary layer is stable and firm, and the quantum dots that are not bound to the auxiliary layer are easily removed. Since the binding force between the auxiliary layer 20 and the substrate 10 is smaller than the binding force between the quantum dots and the auxiliary layer 20, when the auxiliary layer is used as a sacrificial layer, it is easy to be rinsed away, and the quantum dots remained on the auxiliary layer are taken away incidentally, and are not easy to remain in the pixel area, and avoid other colors of quantum dots remaining in the pixel area.

Optionally, the auxiliary layer 20 may be made of an organic material with a thickness of 0.1 nm −1 nm.

In some embodiments, the surface groups may include hydroxyl or carboxyl, the first group may include hydroxyl, carboxyl or double bonds. The hydroxyl may react with a carboxyl or a double bond, so that the first group and the surface group may be bound by chemical bonds, so that the substrate 10 and the auxiliary layer 20 are stably and firmly bound together.

In an embodiment of the present disclosure, the ligand of the quantum dot may include a third group, the third group may include at least one of amino group, hydroxyl group and carboxyl group, and the second group may include at least one of mercapto group, amino group, hydroxyl group, carboxyl group and double bond. The hydroxyl group may react with a carboxyl group or a double bond, and the second group and the third group may undergo a chemical reaction, so that the second group and the third group may be bound by a chemical bond. The auxiliary layer 20 and the ligands of the quantum dots in the quantum dot layer 30 are firmly bound through chemical bonds, and the quantum dots in the quantum dot layer 30 may be stabilized by the auxiliary layer 20.

The auxiliary layer 20 may include at least one of compounds represented by structural formula (1) and structural formula (2). Optionally, the auxiliary layer 20 may include: at least one of 3-mercaptopropyltrimethoxysilane, 3-mercaptopropyl triethoxysilane, 3-mercaptopropylmethyldimethoxysilane, 3-mercaptopropylmethyldiethoxysilane, mercaptopropylsilane, 3-mercaptopropyltrimethylsilane and bis-[3-(triethoxysilyl)propyl]-tetrasulfide. For example, the auxiliary layer 20 may include: 3-mercaptopropyltrimethoxysilane, the mercapto group may form a coordination bond with the surface of the quantum dot, and the surface defect of the quantum dot may be improved by forming the coordination bond. The mercapto group may also be used as a second group, and the ligand of the quantum dot may be bound with the second group through a chemical bond, so that the quantum dots and the auxiliary layer 20 are stably bound.

In some embodiments, the forming the quantum dot layer on the auxiliary layer 20 may include:

the quantum dots are printed in the pixel area of the auxiliary layer 20 to form the quantum dot layer 30.

In the preparation process, the substrate 10 may include the first electrode, the first electrode may be arranged on the substrate, the substrate may be glass, and the glass with the first electrode may be conductive glass, the first carrier transport layer may be formed on the first electrode, the first electrode may be a cathode, the first carrier transport layer may be an electron transport layer. The electron transport layer may include at least one of ZnO, ZnMgO and TiO₂ materials. For example, the electron transport layer may include ZnO, the first carrier transport layer may have surface groups, and the surface groups may be hydroxyl groups. The auxiliary layer 20 may be formed on the first carrier transport layer, the auxiliary layer 20 may be a monomolecular layer, and the auxiliary layer 20 has a first group, the first group is a cross-linking group that may cross-link with the ligand of the quantum dot. In the process of preparing light-emitting devices, by introducing an auxiliary layer, this method may be used to print Active-Matrix Quantum dot Light-Emitting Diodes (AMQLEDs), which may improve the morphology of quantum dot films, the color mixing problem may be effectively solved in AMQLED using photolithography.

As shown in FIG. 7 to FIG. 9, an auxiliary layer 20 may be formed on the first electrode or the electron transport layer on the surface of the first electrode, the auxiliary layer 20 may be a monomolecular layer, and the auxiliary layer 20 may have a silane reagent with mercapto groups, for example, the silane reagent may be 3-mercaptopropyltrimethoxysilane. Taking 3-mercaptopropyltrimethoxysilane monomolecular layer as an example, an ethanol solution of 3-mercaptopropyltrimethoxysilane (3-mercaptopropyltrimethoxysilane 0.5 mL, ethanol 4.5 mL) is prepared, and a small amount of ammonia water (0.1 mL) is added, 90 uL of the above solution is added dropwise onto the above conductive glass, spin-coated to form a film, rotated at 1000-4000 rpm, and left at room temperature for 1-2 h. Then the above conductive glass is rinsed with ultra-dry absolute ethanol for 2-3 times. This step may be done in the air, which may get rid of the dependence on the expensive glove box. In this method, taking 3-mercaptopropyltrimethoxysilane as an example, by controlling the concentration and the spin coating speed of the silane solution, a dense silane-coupled silicon oxide film is formed on the upper film layer. In addition, silane reagents with mercapto groups may be selected from: at least one of 3-mercaptopropyltrimethoxysilane, 3-mercaptopropyl triethoxysilane, 3-mercaptopropylmethyldimethoxysilane, 3-mercaptopropylmethyldiethoxysilane, mercaptopropylsilane, 3-mercaptopropyltrimethylsilane and bis-[3-(triethoxysilyl)propyl]-tetrasulfide.

Graphical quantum dots may be printed on the auxiliary layer 20, quantum dots may be printed in the pixel area of the auxiliary layer 20, and the quantum dots may be fixed on the auxiliary layer 20 through cross-linking or ligand exchange. After pringting the quantum dots are printed on the corresponding position, the leaked second groups in the monomolecular layer, such as mercapto groups, may react with the ligands of the quantum dots, so that the quantum dots are fixed on the auxiliary layer 20, preventing the quantum dot from climbing, increasing the flatness of the quantum dot layer, and optimizing the film morphology of the printed quantum dot.

In other embodiments, the forming the plurality of pixels arranged in the array on the auxiliary layer 20 may include:
depositing the first quantum dot with ligands on the auxiliary layer 20;
exposing the first quantum dot to the first pixel area with the first light, so that the second group in the auxiliary layer 20 is bound with the ligands of the first quantum dots through chemical bonds;
developing the first quantum dot in the unexposed areas; and
flood exposure and development are performed on the unexposed area using the second light to form the first quantum dot layer 31 in the first pixel area. By flood exposure and development, the remaining first quantum dots in the unexposed area may be removed to avoid color mixing.

Optionally, the forming the plurality of pixels arranged in the array on the auxiliary layer 20 may include:
depositing the second quantum dot with ligands on the auxiliary layer 20, in which the first quantum dots and the second quantum dots have different emission wavelengths;
exposing the second quantum dot in the second pixel area with the first light, so that the second group in the auxiliary layer 20 is bound with the ligands of the second quantum dots through chemical bonds;
developing the second quantum dot in the unexposed areas; and
flood exposure and development are performed on the unexposed area using the second light to form the second quantum dot layer 32 in the second pixel area. By flood exposure and development, the remaining second quantum dots in the unexposed area may be removed to avoid color mixing.

Optionally, the forming the plurality of pixels arranged in the array on the auxiliary layer 20 may include:
depositing the third quantum dot with ligands on the auxiliary layer 20, in which the first quantum dots, the second quantum dots, and the third quantum dots have different emission wavelengths;
exposing the third quantum dot in the third pixel area with the first light, so that the second group in the auxiliary layer 20 is bound with the ligands of the third quantum dots through chemical bonds;
developing the third quantum dot in the unexposed areas; and
flood exposure and development are performed on the unexposed area using the second light to form the third quantum dot layer 33 in the third pixel area.

The ligands of the quantum dots may cross-link with the second group in the auxiliary layer 20 through chemical bonds, for example, as shown in FIG. 10, the ligand of the quantum dot and the second group in the auxiliary layer 20 may cross-link under light exposure, so that the ligands of the quantum dots may cross-link with the second groups in the auxiliary layer 20 through chemical bonds. As shown in FIG. 11, the specific preparation process may be as follows:
(1) Cleaning, in which there is a first electrode on the conductive glass, and the conductive glass (ITO or FTO, etc.) is ultrasonically cleaned with water and isopropanol respectively, and treated with UV for 5 to 10 mins.
(2) Introducing an electron transport layer, in which the electron transport layer may be a zinc oxide-based nanoparticle film or a zinc oxide film.

### (a) Preparation of ZnO-Based Nanoparticle Films

Spin-coating zinc oxide nanoparticles, then heating at 80 to 120° C. to form a film; the electron transport layer material may also be selected from ion-doped zinc oxide nanoparticles, such as Mg, In, Al, Ga-doped magnesium oxide nanoparticles, etc., the spin-coater speed may be set from 500 to 2500 rpm to adjust the thickness of the film.

### (b) Preparation of ZnO Films

Dissolving 1 g of zinc acetate (or zinc nitrate, etc.) in 5 mL mixed solution of ethanolamine and n-butanol, placing the above conductive glass in a spin-coater, adding 90 to 120 uL of zinc precursor solution dropwise onto the conductive glass, spin coating, and placing the above conductive glass on a hot stage of 250 to 300° C., and heating to evaporate the solvent.
(3) Forming the auxiliary layer 20, that is, modifying the monomolecular layer on the electron transport layer

The ethanol solution of silane reagent (0.5 mL of silane reagent, 4.5 mL of ethanol) was prepared, the structural formula of the silane reagent may be shown in structural formula (3), and a small amount of ammonia water (0.1 mL) was added, 90 uL of the above solution was added dropwise onto the electron transport layer on the above conductive glass, spin-coated to form a film, the rotating speed was 1000-4000 rpm, and left at room temperature for 1-2 hours. Then, the above conductive glass was rinsed with ultra-dry absolute ethanol for 2-3 times. This step may be completed in the air, which may get rid of the dependence on the expensive glove box: patterning the quantum dots by setting the auxiliary layer without dry etching, but only with cleaning, which reduces the damage to the film layer.

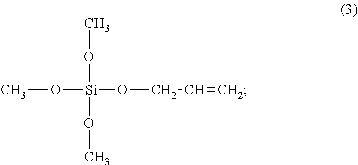

### (4) Patterning Quantum Dots (QD)

The electron transport layer has been modified with a upper monomolecular layer (auxiliary layer 20), and the surface of the auxiliary layer 20 has the second group, which may include double bond cross-linking groups, such as hydroxyl and mercapto groups. The pixel region of the auxiliary layer is coated with the first quantum dot (such as red quantum dot), the deposited ligands of the first quantum dots have the third group, the third group may cross-link with the second group, and the third group may include the double bond, the triple bond, the hydroxyl group, the carboxyl group, etc. The corresponding pixel area was exposed with the first light, so that the ligand of the first quantum dot and the second group of the auxiliary layer 20 may undergo a cross-linking reaction. The first quantum dots in the unexposed part are eluted by developing, and the first quantum dot layer 31 is formed in the corresponding pixel area, but there will be some remaining first quantum dots in the unexposed area. Then, deep ultraviolet (wavelength from 200 nm to 350 nm) light (second light) may be used for flood exposure to dissociate the monomolecular layer from the lower film layer. The monomolecular layer is then developed to eliminate the remaining first quantum dots and prevent color mixing.

The above steps may be repeated to form patterned second quantum dots (such as green light quantum dots) and patterned third quantum dots (such as blue light quantum dots) in corresponding pixel areas, respectively. Further, the patterned second quantum dot layer 32 and the patterned third quantum dot layer 33 are formed in the corresponding pixel area, which may remove other quantum dots remaining in the non-exposed area, prevent color mixing, and form a full-color QLED: the patterning sequence of red light quantum dots, green light quantum dots and blue light quantum dots may also be adjusted as required.

### (5) Introducing the Hole Transport Layer

A hole transport layer may be formed on the quantum dot layer by spin coating or vapor deposition. The hole transport layer may be selected from TFB (poly(9,9-dioctylfluorene-co-N-(4-butylphenyl)diphenylamine)), PVK (polyvinylcarbazole) or hole transport compounds, etc. Among them, the film-forming conditions of TFB may be; forming a film in an inert gas at 130-150° C., the film thickness may be adjusted according to the speed of the spin-coater, and a vapor-deposited hole transport material may also be used in this step.

### (6) Introducing the Hole Injection Layer

The hole injection layer may be formed by spin coating or vapor deposition. The hole injection layer may be selected from PEDOT:PSS 4083 (poly 3,4-ethylenedioxythiophene/polystyrene sulfonate) or other compounds suitable for the hole injection layer, etc. The film forming conditions of PEDOT may be at 130-150° ° C. in the air, the film thickness may be adjusted according to the speed of the spin-coater, and the vapor-deposited hole injection material may also be used in this step.

### (7) Introducing the Anode

Finally, anode materials may be introduced, such as evaporating aluminum film, silver film or sputtering indium zinc oxide (IZO) film to prepare QLED devices.

### (8) Encapsulating

Covering an encapsulating cover plate, and encapsulating the device with ultraviolet curing glue to prepare a quantum dot light-emitting device.

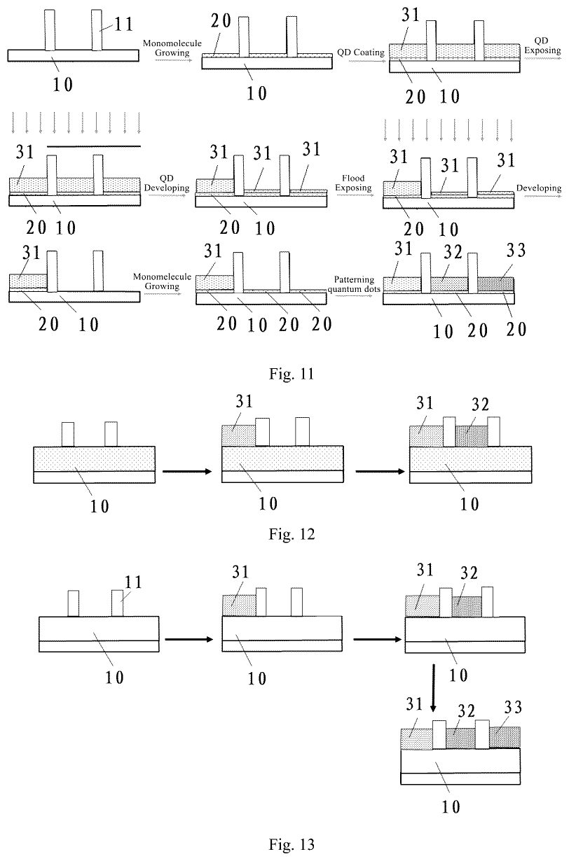

As shown in FIG. 12, the substrate 10 may be a backplate, the backplate may include a light-emitting unit, the light-emitting unit may emit blue light, and the backplate may emit blue light. In the preparation process, the backplate (blue light OLED substrate) may be prepared first, the auxiliary layer may be formed on the substrate 10, and then a quantum dot layer may be formed in the corresponding pixel area on the auxiliary layer. The first quantum dot layer 31 (red light quantum dots) may be formed in the first pixel area, and the second quantum dot layer 32 (green light quantum dots) may be formed in the second pixel area by the above-mentioned preparation method. Since the OLED itself emits blue light, when using the method in the present disclosure to prepare the quantum dot layer, only the patterned red and green pixel regions need to be prepared. For example, the first quantum dot layer 31 (red light quantum dots) is formed in the first pixel area, and the second quantum dot layer 32 (green light quantum dots) is formed in the second pixel area. After the blue light emitted by the backplate passing through the first quantum dot, the first quantum dot may emit red light. After the blue light emitted by the backplate passing through the second quantum dot, the second quantum dot may emit green light. The quantum dot layer may be used as a light conversion layer to convert blue light into other colors of light, and then a full-color light-emitting device may be formed.

As shown in FIG. 13, the substrate 10 may be a backplate, the backplate may include a light-emitting unit, the light-emitting unit may emit blue light, and the backplate may emit white light. In the preparation process, the backplate (white light OLED substrate) may be prepared first, the auxiliary layer may be formed on the substrate 10, and then a quantum dot layer may be formed in the corresponding pixel area on the auxiliary layer by the method in the present disclosure. Since the OLED itself emits white light, when using the method in the present disclosure to prepare the quantum dot layer, the quantum dot layers may be formed in the first pixel area, the second pixel area and the third pixel area, respectively. First, the first quantum dots (red light quantum dots) are formed in the first pixel area to form the first quantum dot layer 31. Then, the second quantum dots (green light quantum dots) are formed in the second pixel area to form the second quantum dot layer 32. Finally, the third quantum dots (blue light quantum dots) are formed in the third pixel area to form the third quantum dot layer 33. After the white light emitted by the backplate passing through the first quantum dot, the first quantum dot may emit red light. After the white light emitted by the backplate passing through the second quantum dot, the second quantum dot may emit green light. After the white light emitted by the backplate passing through the third quantum dot, the third quantum dot may emit blue light. The quantum dot layer may be used as a light conversion layer to convert white light into other colors of light, and then a full-color light-emitting device may be formed.

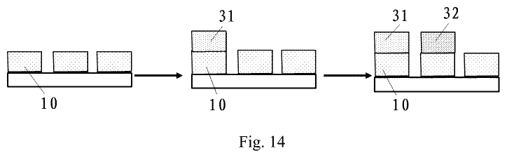

As shown in FIG. 14, the substrate 10 may be a backplate, the backplate may include a light-emitting unit, the light-emitting unit may emit blue light, and the backplate may emit blue light. In the preparation process, the backplate (blue light Micro LED substrate) may be prepared first, the light-emitting materials in blue micro LED may include gallium nitride (GaN), the auxiliary layer may be formed on the substrate 10, and then a quantum dot layer may be formed in the corresponding pixel area on the auxiliary layer. The first quantum dot layer 31 (red light quantum dots) may be formed in the first pixel area, and the second quantum dot layer 32 (green light quantum dots) may be formed in the second pixel area by the above-mentioned preparation method in present disclosure. Since the Micro LED itself emits blue light, when using the method in the present disclosure to prepare the quantum dot layer, only the patterned red and green pixel area are needed to be prepared, for example, the first quantum dots are formed in the first pixel area to form the first quantum dot layer 31 (red light quantum dots), and the second quantum dots are formed in the second pixel area to form the second quantum dot layer 32 (green light quantum dots). After the blue light emitted by the backplate passing through the first quantum dot, the first quantum dot may emit red light. After the blue light emitted by the backplate passing through the second quantum dot, the second quantum dot may emit green light. The quantum dot layer may be used as a light conversion layer to convert blue light into other colors of light, and then a full-color light-emitting device may be formed.

The present disclosure provides a display panel, including the light-emitting device described in the above embodiments. The display panel with the light-emitting device in the above-mentioned embodiment has good display effect, and is not prone to appear color mixing, which may improve the user's experience.

The present disclosure provides a display device, including the display panel described in the above embodiments. The display device with the display panel device in the above-mentioned embodiment has good display effect, has no color mixing, and has good use experience.

The embodiments of the present invention have been described above in conjunction with the accompanying drawings, but the present invention is not limited to the above-mentioned specific embodiments. The above-described specific embodiments are merely illustrative and not restrictive. Under the inspiration of the present invention, those of ordinary skill in the art can also make many forms without departing from the spirit of the present invention and the scope protected by the claims, which all belong to the protection of the present invention.

1. A light-emitting device, comprising:
a substrate; and
an auxiliary layer and a quantum dot layer that are arranged in sequence on one side of the substrate;
wherein the auxiliary layer has a first group and a second group, the first group and a surface group of the substrate are bound with each other through a chemical reaction, and the second group and ligands of quantum dots in the quantum dot layer are bound with each other through a chemical reaction, and a binding force between the auxiliary layer and the substrate is smaller than a binding force between the quantum dots and the auxiliary layer.

2. The light-emitting device of claim 1, wherein the second group and the ligands of the quantum dots in the quantum dot layer are bound with each other through a ligand exchange or cross-linking reaction.

3. The light-emitting device of claim 2, wherein the first group is arranged close to the substrate, and the second group is arranged close to the quantum dot layer.

4. The light-emitting device of claim 3, wherein the auxiliary layer is made of an organic material and has a thickness of 0.1 nm-1 nm.

5. The light-emitting device of claim 4, wherein the auxiliary layer comprises at least one of compounds represented by structural formula (1) and structural formula (2), 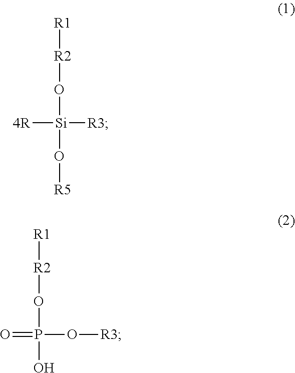
wherein R1 comprises at least one of a benzene ring-conjugated double bond, a carbon-oxygen double bond, a carbon-carbon double bond, a carbon-nitrogen double bond, hydroxyl, carboxyl, and mercapto, R2 is a carbon chain with a saturated or unsaturated bond, R3 comprises at least one of alkoxy, acetoxy and halogen, R4 comprises at least one of alkoxy, acetoxy and halogen, and R5 comprises at least one of alkoxy, acetoxy and halogen.

6. The light-emitting device of claim 5, wherein the auxiliary layer comprises:
at least one of 3-mercaptopropyltrimethoxysilane, 3-mercaptopropyl triethoxysilane, 3-mercaptopropylmethyldimethoxysilane, 3-mercaptopropylmethyldiethoxysilane, mercaptopropylsilane, 3-mercaptopropyltrimethylsilane and bis-[3-(triethoxysilyl)propyl]-tetrasulfide.

7. The light-emitting device of claim 6, wherein the light-emitting device has a plurality of pixels arranged in an array, each of the pixels comprises a first sub-pixel and a second sub-pixel, a spacer structure is provided on the substrate, and a minimum area enclosed by adjacent spacer structures constitutes a sub-pixel; and
the quantum dot layer comprises a first quantum dot and a second quantum dot, the first quantum dot is arranged in the first sub-pixel, and the second quantum dot is arranged in the second sub-pixel, and the first quantum dot and the second quantum dot have different emission wavelengths.

8. The light-emitting device of claim 7, wherein the substrate further comprises a first electrode and a first carrier transport layer that are laminated one on another, and the first carrier transport layer is arranged closer to the auxiliary layer.

9. The light-emitting device of claim 7, wherein the substrate further comprises a backplate, the backplate comprises a light-emitting unit, and light having a first wavelength band emitted by the light-emitting unit, after passing through the first quantum dot, becomes light having a second wavelength band to be emitted; the light having the first wavelength band emitted by the light-emitting unit, after passing through the second quantum dot, becomes light having a third wavelength band; and
the binding force between the auxiliary layer and the substrate is greater than a binding force between the auxiliary layer and the spacer structure.

10. The light-emitting device of claim 8, wherein each of the pixels further comprises a third sub-pixel, the quantum dot layer is correspondingly provided with a third quantum dot, the third quantum dot is arranged in the third sub-pixel, and the first quantum dot, the second quantum dot and the third quantum dot have different emission wavelengths.

11. The light-emitting device of claim 10, wherein the light-emitting device further comprises:
a second carrier transport layer arranged on the side of the quantum dot layer away from the substrate;
a second electrode arranged on the side of the second carrier transport layer away from the substrate.

12. The light-emitting device of claim 7, wherein the binding force between the auxiliary layer and the substrate is greater than a binding force between the auxiliary layer and the spacer structure.

13. A preparation method of a light-emitting device, comprising:
providing a substrate; and
forming an auxiliary layer and a quantum dot layer in sequence on one side of the substrate;
wherein the auxiliary layer has a first group and a second group, the first group and a surface group of the substrate are bound with each other through a chemical reaction, the second group and ligands of quantum dots in the quantum dot layer are bound with each other through a chemical reaction, and a binding force between the auxiliary layer and the substrate is smaller than a binding force between the quantum dots and the auxiliary layer.

14. The preparation method of claim 13, wherein the second group and the ligands of the quantum dots in the quantum dot layer are bound with each other through a ligand exchange or cross-linking reaction.

15. The preparation method of claim 13, wherein the forming the auxiliary layer and the quantum dot layer in sequence on one side of the substrate comprises:
forming an auxiliary layer on one side of the substrate; and
forming a plurality of pixels arranged in an array on the auxiliary layer;
wherein each of the pixels comprises a first sub-pixel and a second sub-pixel, the quantum dot layer comprises a first quantum dot and a second quantum dot, the first quantum dot is formed in the first sub-pixel, and the second quantum dot is formed in the second sub-pixel, a minimum area enclosed by adjacent spacer structures on the substrate constitutes a sub-pixel, and the first quantum dot and the second quantum dot have different emission wavelengths.

16. The preparation method of claim 15, wherein each of the pixels further comprises a third sub-pixel, the quantum dot layer is correspondingly provided with a third quantum dot, the third quantum dot is formed in the third sub-pixel, and the first quantum dot, the second quantum dot and the third quantum dot have different emission wavelengths.

17. The preparation method of claim 15, wherein the binding force between the auxiliary layer and the substrate is greater than a binding force between the auxiliary layer and the spacer structure.

18. A display panel, comprising the light-emitting device of claim 1.

19. A display device, comprising the display panel of claim 18.
